(19) United States
(12) Patent Application Publication
(10) Pub. No.: US 2018/0342460 A1
(43) Pub. Date: Nov. 29, 2018

(54) METHOD AND APPARATUS FOR FRAGMENTARY METAL BETWEEN M1 AND M2 FOR IMPROVING POWER SUPPLY

(71) Applicant: QUALCOMM Incorporated, San Diego, CA (US)

(72) Inventors: Sreedhar Gudala, San Diego, CA (US); Paras Gupta, San Diego, CA (US); Ranganayakulu Konduri, San Diego, CA (US)

(21) Appl. No.: 15/605,843

(22) Filed: May 25, 2017

(51) Int. Cl. H01L 23/528; H01L 23/48; G06F 17/50

(52) U.S. Cl. CPC H01L 23/5286; G06F 17/5081; H01L 23/481

(57) ABSTRACT

In certain aspects of the disclosure, a chip includes a power distribution network for distributing power to device on the chip. The power distribution network includes a first portion formed from a first metal layer on the chip, a second portion formed from a second metal layer on the chip, and vias interconnecting the first and second portions of the power distribution network, wherein the vias include a first plurality of vias and a second plurality of vias, each one of the first plurality of vias has a first via size, and each one of the second plurality of vias has a second via size. The devices on the chip are electrically coupled to the first portion of the power distribution network.

### RELATED APPLICATION

### Background

### Field

Aspects of the present disclosure relate generally to power distribution on a chip, and more particularly, to improving power efficiency of a power distribution network on a chip.

### Background

A chip (die) typically includes a power distribution network (PDN) for distributing power from a power source to devices (e.g., transistors) on the chip. The power source may be external to the chip. The PDN is formed from multiple metal layers and vias on the chip, and may include one or more power grids for distributing power to different areas of the chip.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A first aspect relates to a chip including a power distribution network. The power distribution network includes a first portion formed from a first metal layer on the chip, a second portion formed from a second metal layer on the chip, and vias interconnecting the first and second portions of the power distribution network, wherein the vias include a first plurality of vias and a second plurality of vias, each one of the first plurality of vias has a first via size, and each one of the second plurality of vias has a second via size. The chip also includes devices electrically coupled to the first portion of the power distribution network.

A second aspect relates to a chip including a power grid. The power grid includes a first plurality of power rails formed from a first metal layer on the chip, a second plurality of power rails formed from a second metal layer on the chip, and vias interconnecting the first plurality of power rails and the second plurality of power rails, wherein the vias include a first plurality of vias and a second plurality of vias, each one of the first plurality of vias has a first via size, and each one of the second plurality of vias has a second via size. The chip also includes devices electrically coupled to the first plurality of power rails.

A third aspect relates to a computer-implemented method for chip design. The method includes retrieving a file specifying vias that interconnect first and second portions of a power distribution network on a chip. The method also includes, for each one of the vias, selecting a first via size or a second via size for the via based on one or more design rules for the chip.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of a few of the various ways in which the principles of various embodiments may be employed and the described embodiments are intended to include all such aspects and their equivalents.

### BRIEF DESCRIPTION OF THE DRAWINGS

FIG. 1 shows an example of a power distribution network for a chip.

FIG. 2 shows an example of a power grid according to certain aspects of the present disclosure.

FIG. 3 shows a side view of vias between metal layers M1 and M2 of a power distribution network.

FIG. 4 shows a side view of vias between metal layers M1 and M2 of a power distribution network, in which the vias include a mix of different sizes and shapes according to certain aspects of the present disclosure.

FIG. 5 shows a top view of two vias having different sizes and shapes according to certain aspects of the present disclosure.

FIG. 6 shows an example of an electronic design automation (EDA) system according to certain aspects of the present disclosure.

FIG. 7 is a flowchart illustrating a method for chip design according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

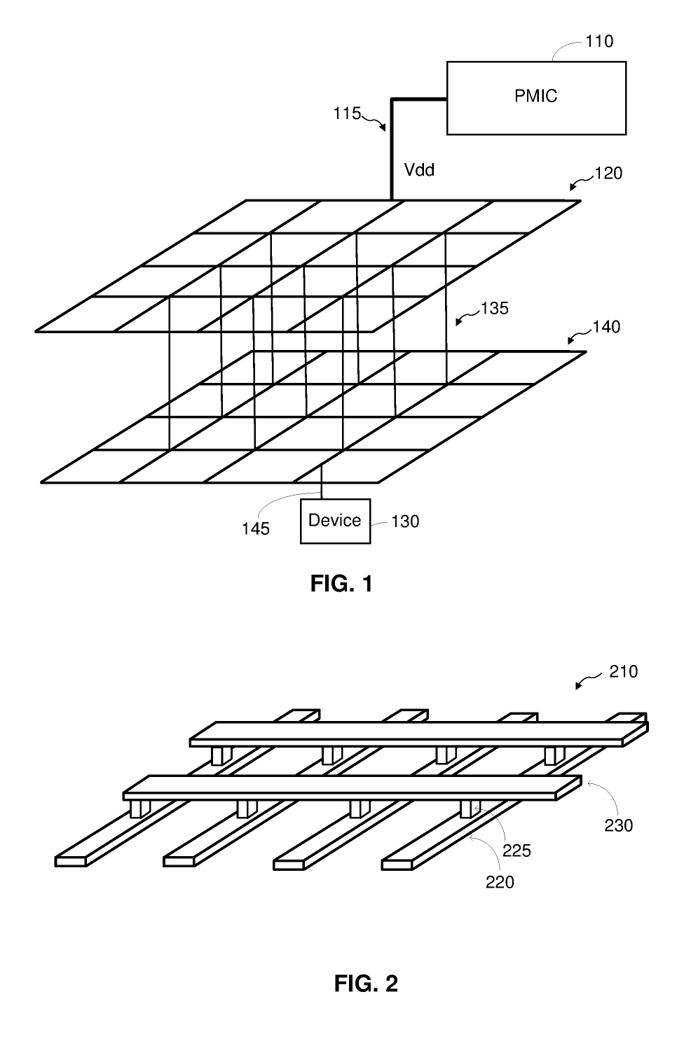

Devices (e.g., transistors) on a chip typically receive power from a power source (e.g., an external power source) via a power distribution network (PDN). In this regard, FIG. 1 shows an example of a PDN configured to deliver power from a power management integrated circuit (PMIC) 110 or another power source to devices (e.g., transistors) on a chip. For ease of illustration, only one of the devices 130 on the chip is shown in FIG. 1. The PMIC 110 provides a supply voltage Vdd to the PDN for powering the devices on the chip, and may be external to the chip. The PMIC 110 may include one or more voltage regulators (e.g., switching regulator and/or linear regulator) that convert a voltage from a battery or another voltage source into the supply voltage Vdd, which is typically a direct current (DC) voltage.

The PDN may include power grids (also referred to as power meshes) on the chip (also referred to as a die). In the example shown in FIG. 1, the PDN includes a global power grid 120 and a local power grid 140 on the chip. The global power grid 120 may be formed from upper metal layers on the chip, and the local power grid 140 may be formed from lower metal layers on the chip. The PDN also includes interconnects 135 that electrically couple the global power grid 120 to the local power grid 140. The interconnects 135 may be formed from multiple metal layers and vias on the chip, as discussed further below. The global power grid 120 is electrically coupled to the PMIC 110 via power line 115. For the example in which the PMIC 110 is external to the chip, the PMIC 110 and the chip may be mounted on a printed circuit board or another substrate, and the power line 115 may include one or more conductive traces on the printed circuit board or other substrate. The device 130 is electrically coupled to the local power grid 140 by a contact 145 to receive power from the PDN.

The global power grid 120 is used to distribute power from the PMIC 110 to different areas of the chip. The local power grid 140 is located near the devices (e.g., transistors) on the chip, and is used to distribute power locally to the devices on the chip. Although FIG. 1 depicts the global power grid 120 and the local power grid 140 as having the same pattern for simplicity, it is to be appreciated that this need not be the case. The metal lines of the local power grid 140 may be finer and more closely spaced together than the metal lines of the global power grid 120, which is formed from the upper metal layers on the chip.

The power grids 120 and 140 and interconnects 135 have resistance, which result in IR voltage drops in the PDN. The IR voltage drops reduce the supply voltage reaching the devices (e.g., transistors) on the chip, thereby reducing the power efficiency of the PDN. Therefore, it is desirable to reduce resistance in the PDN to improve power efficiency, as discussed further below.

The local power grid 140 may be formed from one or more metal layers on the chip. In this regard, FIG. 2 shows an example of a power grid 210 that may be used to implement the local power 140. The power grid 210 includes a first set of power rails 220 formed from a first metal layer on the chip, and a second set of power rails 230 formed from a second metal layer on the chip above the first metal layer. The power rails may also be referred to as metal wires, metal lines, or another terminology. Each power rail extends in a lateral direction on the chip.

The first set of power rails 220 is electrically coupled to the second set of power rails 230 by vias 225 between the first and second metal layers. In the example shown in FIG. 2, each of the power rails in the first set of power rails 220 is coupled to one of the power rails in the second set of power rails 230 by a respective one of the vias 225. Each via extends in a vertical direction on the chip, and provides an electrical interconnect between rails formed from different metal layers.

The first set of power rails 220 may be electrically coupled to devices (not shown in FIG. 2) below the first metal layer to deliver power to the devices. The second set of power rails 220 may be electrically coupled to the global grid 120 by interconnects (e.g., interconnects 135 shown in FIG. 1), which may be formed from multiple metal layers and vias on the chip disposed between the second metal layer and the one or more upper metal layers used to form the global power grid 120.

In the example shown in FIG. 2, the power rails in the first set of power rails 220 run parallel to one another, and the power rails in the second set of power rails 230 run parallel to one another. The power rails in the first set of power rails 220 run perpendicular to the power rails in the second set of power rails 230. In other words, the power rails in the first set of power rails 220 are orientated perpendicular with respect to the power rails in the second set of power rails 230.

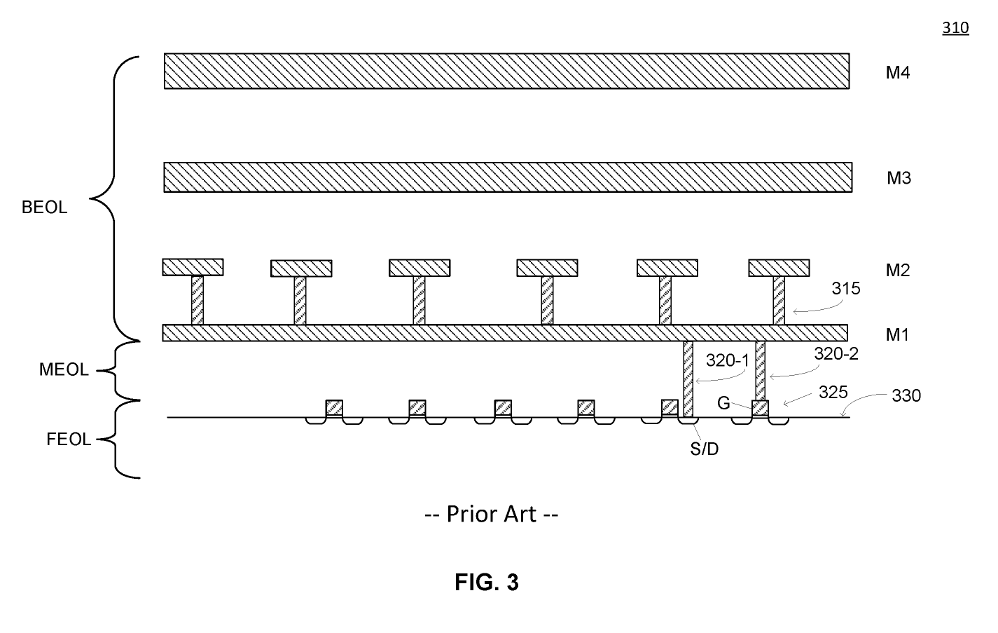

FIG. 3 shows an example of different layers on a semiconductor chip 310 (also referred to as a die). The chip 310 includes multiple interconnect metal layers in a back end of line (BEOL) of the chip, in which adjacent interconnect metal layers are separated by one or more insulating layers. The bottom-most interconnect metal layer is labeled M1. The interconnect metal layer immediately above interconnect metal layer M1 is labeled M2, the interconnect metal layer immediately above metal layer M2 is labeled M3, and so forth. Although four interconnect metal layers M1-M4 are shown in FIG. 3, for ease of illustration, it is to be understood that the chip 310 may include additional metal layers above metal layer M4. For example, a chip fabricated with a nanometer process may include eight or more metal layers. It is to be appreciated that metal layers may also be referred to as metallization layers, or another terminology. Each metal layer extends in a lateral direction on the chip.

The different metal layers are interconnected using vias. Each via may be a vertical interconnect structure that interconnects two adjacent metal layers. For ease of illustration, only the vias 315 between metal layers M1 and M2 are shown in FIG. 3. The metal layers M1 -M4 may be patterned using photolithography or another process to form part of the PDN. For example, metal layers M1 and M2 may be patterned to form the local power grid 140, and metal layers M3 and M4 may be patterned (not shown) to form part of the interconnects (e.g., interconnects 135 shown in FIG. 1) between the local power grid 140 and the global power grid 120. The global power grid 120 may be formed from upper metal layers (not shown) above metal layer M4.

The metal layers M1-M4 may also be patterned to form signal lines (not shown) for routing signals to/from the devices on the chip. The signals may include digital signals, analog signals, etc. Thus, a portion of the metal layers may be used to form signal lines for the devices on the chip and another portion of the metal layers may be used to form part of the PDN.

The chip 310 also includes devices 325 in a front end of line (FEOL) of the chip 310. The devices 325 may be fabricated on the substrate 330 of the chip 310 using a planer process and/or a non-planer process. The devices 325 may include planer field-effect transistors (depicted in FIG. 3), FinFETs and/or other types of transistors. The devices may be grouped into cells, in which the transistors in a cell may be interconnected to form a circuit (e.g., a logic gate, a multiplexer, a flip-flop, etc.).

The chip 310 also includes contacts in a middle end of line (MEOL) of the chip. The contacts may be used to electrically couple the devices 325 to metal layer M1 for power delivery and signal routing. In this regard, FIG. 3 shows an example of a contact 320-1 between a source or drain (labeled “S/D”) of one of the devices 325 and metal layer M1, and a contact 320-2 between a gate (labeled “G”) of another one of the devices 325 and metal layer M1. The chip may also include local interconnects (not shown) in the MEOL to interconnect transistors within a cell.

As discussed above, metal layers M1 and M2 may be patterned to form part of the PDN. For example, metal layers M1 and M2 may be patterned to form local power grid 140. Using the example in FIG. 2, metal layer M1 may be patterned to form the first set of power rails 220, and metal layer M2 may be patterned to form the second set of power rails 230. In this example, the vias 315 correspond to the vias 225 in FIG. 2. In another example, metal layer M1 may be patterned to form the local power grid 140, and metal layer M2 may be patterned to form part of the interconnects between the local grid 140 and the global grid 120.

Currently, all of the vias 315 between metal layers M1 and M2 have the same size (i.e., same dimensions). The via size is selected such that the vias are able to comply with a set of design rules throughout the entire chip (die). The design rules may include, e.g., minimum spacing between vias to account for process variation, an enclosure rule specifying that a via be covered by a metal layer with a minimum amount of additional margin, etc. A drawback of using a single via size is that the via size typically has to be small in order to work throughout the entire chip, especially as feature sizes are reduced for advanced processes. The small via size results in higher resistance for each via, which results in higher power dissipation (e.g., IR drops) in the PDN.

In certain areas of the chip, larger-sized vias with lower resistance can be used while still complying with the design rules. However, this is prevented by the use of a single via size for the entire chip, which is required to work throughout the entire chip. As a result, opportunities to use larger-sized vias in areas of the chip that can accommodate them without violating the design rules are missed. Thus, the traditional approach of using one via size between metal layers M1 and M2 is not power efficient.

Aspects of the present disclosure improve power efficiency by using more than one via size for the vias between metal layers M1 and M2 without impacting the design rules. In some embodiments, a first via size and a second via size are used for vias between metal layers M1 and M2, in which the second via size is larger than the first via size. The first via size may be the via size used in the conventional approach discussed above, while the second via size is larger (and hence results in lower resistance) than the first via size. The second via size may have approximately the same height as the first via size, but a larger width for lower resistance. For example, the second via size may have approximately double the width of the first via size. As discussed further below, the second via size is used for vias for which the second via size does not cause a design rule violation. As a result, resistance is lowered in these vias, improving the power efficiency of the PDN.

In certain aspects, an electronic design automation (EDA) system determines which vias on a chip can be implemented using the second via size (i.e., larger via size) for a given chip layout (e.g., layout of cells) and design rules without violating the design rules. The remaining vias are implemented using the first via size (i.e., smaller via size). An example of an EDS system is discussed below with reference to FIG. 6.

For example, the EDA system may start with all of the vias between metal layers M1 and M2 on a chip having the first via size (i.e., smaller via size). The EDA system may then change the sizes of one or more of the vias from the first via size to the second via size, and check whether the change results in a design rule violation. If the change does not result in a design rule violation, then the EDA system keeps the change. If the change results in a design rule violation, then the EDA system may undo the change. The EDA system may perform the above steps for all of the vias between metal layers M1 and M2 on the chip. Thus, the EDA system determines which vias can be changed to the second via size without violating the design rules, and changes these vias. This way, the EDA system takes advantage of opportunities where the larger via size (i.e., second via size) can be used on the chip without violating the design rules.

In one exemplary case in which the above approach was carried out for a chip for a nanometer process, approximately 50% of the vias between metal layers M1 and M2 on the chip were changed from the first via size to the second via size. Thus, in this case, the above approach resulted in approximately 50% of the vias having the first via size and approximately 50% of the vias having the second via size. Because the second via size is larger than the first via size, this approach resulted in lower resistance in the PDN compared to the case where all of the vias have the first via size, thereby improving the power efficiency of the PDN.

Note that the above approach does not require changing the number of vias on the chip, the underlying circuit layout (e.g., layout of cells underneath metal layer M1), or the design rules. This reduces the impact of the above approach on the design flow of the chip, thereby reducing the cost of implementing the above approach.

The above approach results in a chip in which the vias between metal layer M1 and metal layer M2 include a mix of vias having the first via size and vias having the second via size. The distribution of the via sizes may be non-uniform, and depend on the layout of the cells on the chip and the design rules.

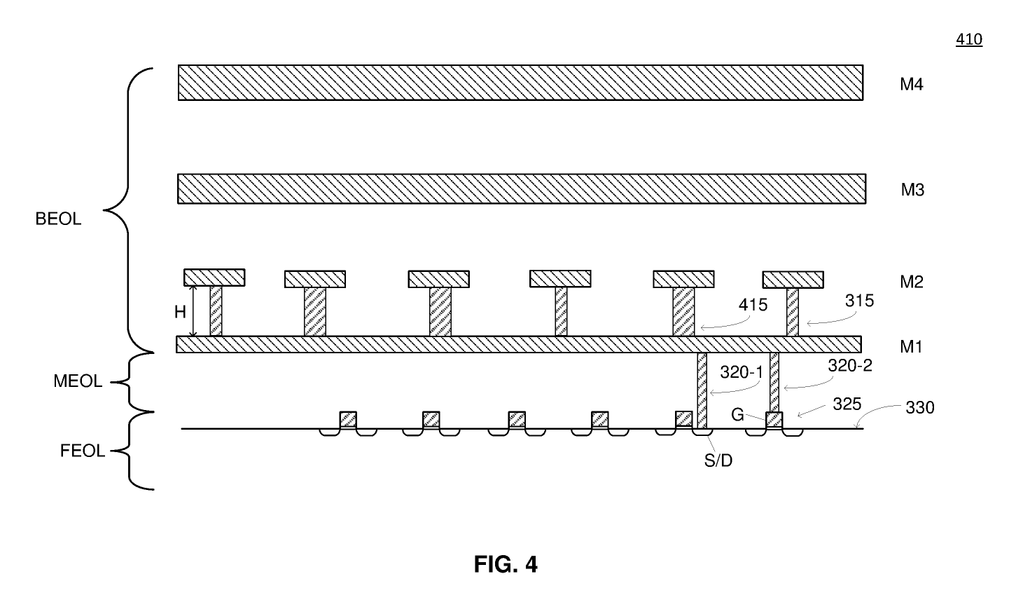

FIG. 4 shows an example in which the vias between metal layers M1 and M2 include a first set of vias 315 having the first via size and a second set of vias 415 having the second via size. The vias 315 and 415 shown in FIG. 4 may result from applying the above approach to the vias 315 shown in FIG. 3, in which the vias that can be changed from the first vias size to the second via size without violating the design rules for the chip are changed while the remaining vias are left unchanged.

As shown in the example in FIG. 4, the vias in the first set of vias 315 and the vias in the second set of vias 415 have the same height, but different widths. In FIG. 4, height (labeled “H”) refers to the dimension of the vias in the vertical direction, which is perpendicular to the metal layers M1 and M2.

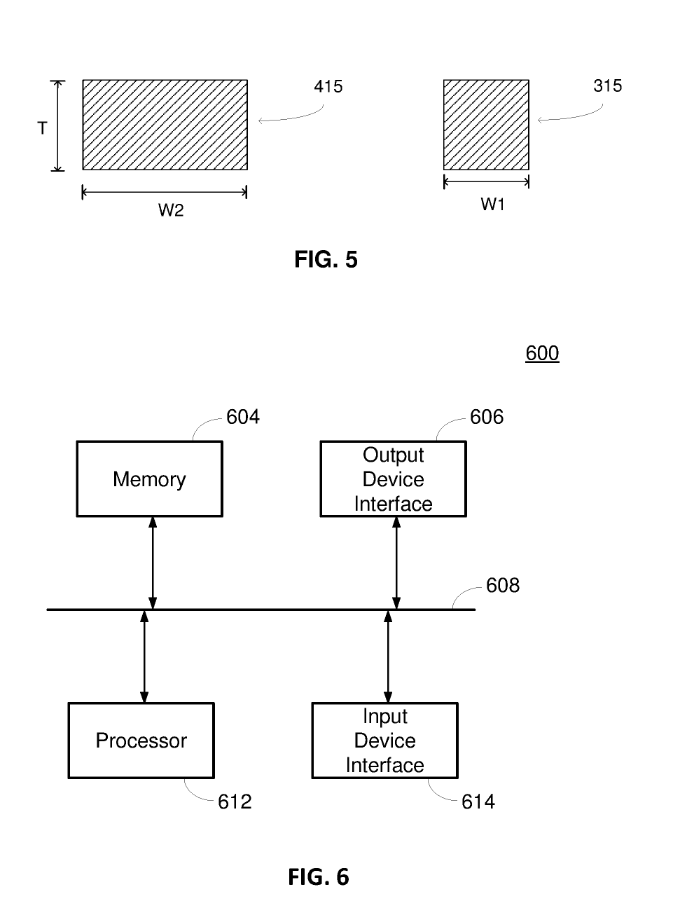

More particularly, the vias in the second set of vias 415 have a wider width than the vias in the first set of vias 315 (e.g., approximately double the width), resulting in lower resistance for the vias in the second set of vias 415 compared with the vias in the first set of vias 315. In this regard, FIG. 5 shows a top view of one of the vias in the first set of vias 315, and one of the vias in the second set of vias 415. As shown in FIG. 5, the width (labeled “W2”) of the via in the second set of vias 415 is wider than the width (labeled “W1”) of the via in the first set of vias 315. For example, the width W2 of the via in the second set of vias 415 may be approximately double the width W1 of the via in the first set of vias 315. The widths W1 and W2 are taken in a lateral direction of the chip.

In the example shown in FIG. 5, the via in the second set of vias 415 and the via in the first set of vias 315 have approximately the same dimension (labeled “T”) in a lateral direction that is perpendicular to the lateral direction of the widths W1 and W2. However, it is to be appreciated that this need not be the case, and that the via in the second set of vias 415 and the via in the first set of vias 315 may have different dimensions in both lateral directions.

In the example shown in FIG. 5, the via in the first set of vias 315 has approximately a square shape looking from the top, and the via in the second set of vias 415 has approximately a rectangular shape looking from the top. Thus, the vias in the first set of vias 315 have a different shape than the vias in the second set of vias 415.

In certain aspects, the width W2 of the vias in the second set of vias 415 is at least 50 percent wider than the width W1 of the vias in the first set of vias 315. In certain aspects, the PDN includes multiple vias between metal layers M1 and M2 in which about 30 to 70 percent of the vias belong to the first set of vias 315 and the remaining vias belong to the second set of vias 415.

As discussed above, metal layers M1 and M2 may be patterned to form part of the PDN. Using the example in FIG. 2, metal layer M1 may be patterned to form the first set of power rails 220, and metal layer M2 may be patterned to form the second set of power rails 230. In this example, the vias in the first set of vias 315 and the vias in the second set of vias 415 correspond to the vias 225 in FIG. 2. In other words, the vias coupling the first set of power rails 220 to the second set of power rails 230 include a mix of vias having the first via size and vias having the second via size. In this example, the distribution of vias having the first vias size and distribution of vias having the second via size may be may be non-uniform, and depend on the layout of the cells on the chip and the design rules.

In another example, metal layer M1 may be patterned to form the local power grid 140, and metal layer M2 may be patterned to form part of the interconnects (e.g., interconnects 135 in FIG. 1) between the local grid 140 and the global grid 120. In this example, the vias between metal layers M1 and M2 form part of the interconnects between the local grid 140 and the global grid 120. _{|[A1]}

As discussed above, an EDA system may be used to determine which vias between metal layers M1 and M2 of a PDN can be implemented using the second via size (i.e., larger via size) for a given chip layout and design rules without violating the design rules. In this regard, FIG. 6 shows an example of an EDA system 600. The EDA system 600 includes a bus 608, a processor 612, a memory 604, an input device interface 614, and an output device interface 606. The bus 608 collectively represents all system buses that communicatively couple the numerous devices of the EDA system 600. For instance, the bus 608 communicatively couples the processor 612 with the memory 604.

In operation, the processor 612 may retrieve instructions from the memory 604 for performing one or more of the functions described herein, and execute the instructions to perform the one or more functions. The processor 612 may be a single processor or a multi-core processor. The memory 604 may include a random access memory (RAM), a read only memory (ROM), a flash memory, registers, a hard disk, a removable disk, a CD-ROM, or any combination thereof.

The bus 608 may also couple to the input and output device interfaces 614 and 606. The input device interface 614 may enable a user to communicate information and enter commands to the EDA system 600, and may include, for example, an alphanumeric keyboard and a pointing device (e.g., a mouse). For example, the user may use the input device interface 614 to enter a command to the processor 612 to control operations of the processor 612. The output device interface 606 may enable, for example, the display of information generated by the EDA system 600 to a user, and may include, for example, a display device (e.g., liquid crystal display (LCD)).

In certain aspects, the processor 612 of the EDA system 600 retrieves a file from the memory 604 or another memory, in which the file specifies a chip design. The chip design may include a layout of cells underneath metal layer M1. The chip design may also include vias between metal layers M1 and M2, which are part of the PDN of the chip.

In some embodiments, all of the vias between metal layers M1 and M2 in the file may initially have the first via size (i.e., smaller via size). The processor 612 may then change the sizes of one or more of the vias from the first via size to the second via size, and check whether the change causes a violation of one or more design rules for the chip. The design rules may be stored on the memory 604 and retrieved by the processor 612. If the change does not result in a design rule violation, then the processor 612 system keeps the change. If the change results in a design rule violation, then the EDA system may undo the change. The processor 612 may perform the above steps for all of the vias between metal layers M1 and M2 on the chip that are part of the PDN. This results in the vias between metal layers M1 and M2 including a mix of vias having the first via size and vias having the second via size. The distribution of the via sizes may be non-uniform, and depend on the layout of the cells in the chip design and the design rules for the chip.

In some embodiments, all of the vias between metal layers M1 and M2 in the file may initially have the second via size (i.e., larger via size). The processor 612 may then apply the design rules to one or more of the vias to determine whether the one or more vias violate one or more of the design rules. If the one or more vias do not violate one or more of the design rules, then the processor 612 leaves the one or more vias unchanged. If the one or more vias violate one or more of the design rules, then the processor 612 changes the one or more vias to the first via size (i.e., smaller via size). The processor 612 may perform the above steps for all of the vias between metal layers M1 and M2 on the chip that are part of the PDN. This results in the vias between metal layers M1 and M2 including a mix of vias having the first via size and vias having the second via size. The distribution of the via sizes may be non-uniform, and depend on the layout of the cells in the chip design and the design rules for the chip.

After determining which vias can be implemented using the second via size, the processor 612 may generate a new file specifying a chip design, in which the vias between metal layers M1 and M2 include a mix of vias having the first via size and vias having the second via size determined above. The layout of the cells underneath metal layer M1 in the new file may be the same as the original file. Also, the number and/or placement of the vias in the new file may be the same as the original file. This helps minimize changes to the chip design in the new file compared with the original file, thereby reducing cost and delay in the design flow.

During chip fabrication, the vias between metal layers M1 and M2 of the PDN are fabricated according to the mix of vias having the first via size and vias having the second via size determined above. For example, the vias may be formed using photolithography, in which one or more photo masks define the patterns of the vias. For instance, the one or more masks may define the vias by defining via holes that are etched into an insulating layer deposited on metal layer M1. After the via holes are formed, the via holes may be filled with one or more metals to form the vias, and metal layer M2 may be deposited over the vias.

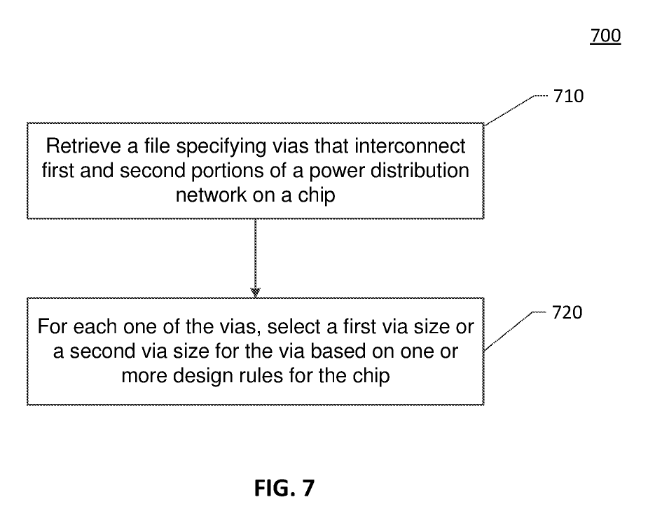

FIG. 7 is flowchart illustrating a computer-implemented method 700 for chip design according to certain aspects of the present disclosure. The method 700 may be performed by the EDA system 600.

At step 710, a file is retrieved specifying vias that interconnect first and second portions of a power distribution network on a chip. The first portion of the power distribution network may be formed from metal layer M1 of a back end of line (BEOL) of the chip, and the second portion of the power distribution network may be formed from metal layer M2 of the BEOL of the chip.

At step 720, for each one of the vias, a first via size or a second via size is selected for the via based on one or more design rules for the chip. For example, selecting the first via size or the second via size for each one of the vias may include determining whether giving the via the second via size violates the one or more design rules. In this example, if giving the via the second via size violates the one or more design rules, then the first via size is selected for the via. If giving the via the second via size does not violate the one or more design rules, then the second via size is selected for the via.

It is to be understood that vias having the first via size in a chip design may be subject to a small degree of process size variation on a physical chip, which is unavoidable in semiconductor fabrication processes. Therefore, within this disclosure, it is to be understood that vias having the first via size are not required to have exactly the same via size, but have the first via size within the process size variation of the fabrication process used to fabricate the chip. The same holds for vias having the second via size.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two components.

It is to be understood that the present disclosure is not limited to the specific order or hierarchy of steps in the methods disclosed herein. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. A chip, comprising:
a power distribution network comprising:
a first portion formed from a first metal layer on the chip;
a second portion formed from a second metal layer on the chip, wherein the first metal layer is metal layer M1 of a back end of line (BEOL) of the chip, and the second metal layer is metal layer M2 of the BEOL of the chip; and
vias interconnecting the first and second portions of the power distribution network, wherein the vias include a first plurality of vias and a second plurality of vias, each one of the first plurality of vias has a first via size, each one of the second plurality of vias has a second via size, and the first and the second plurality of vias have a same height; and
devices electrically coupled to the first portion of the power distribution network.

2. (canceled)

3. The chip of claim 1, wherein the second via size has a width that is at least 50 percent wider than a width of the first via size.

4. (canceled)

5. The chip of claim 1, wherein the first plurality of vias make up between 30 percent and 70 percent of the vias interconnecting the first and second portions of the power distribution network.

6. The chip of claim 1, wherein the devices include transistors.

7. The chip of claim 1, wherein the second portion of the power distribution network is electrically coupled to a power source, and the power distribution network is configured to deliver power from the power source to the devices.

8. The chip of claim 7, wherein the power source is external to the chip.

9. A chip, comprising:
a power grid comprising:
a first plurality of power rails formed from a first metal layer on the chip;
a second plurality of power rails formed from a second metal layer on the chip, wherein the first metal layer is metal layer M1 of a back end of line (BEOL) of the chip, and the second metal layer is metal layer M2 of the BEOL of the chip; and
vias interconnecting the first plurality of power rails and the second plurality of power rails, wherein the vias include a first plurality of vias and a second plurality of vias, each one of the first plurality of vias has a first via size, and each one of the second plurality of vias has a second via size, and the first and the second plurality of vias have a same height; and
devices electrically coupled to the first plurality of power rails.

10. (canceled)

11. The chip of claim 9, wherein the second via size has a width that is at least 50 percent wider than a width of the first via size.

12. (canceled)

13. The chip of claim 9, wherein the first plurality of vias make up between 30 percent and 70 percent of the vias interconnecting the first plurality of power rails and the second plurality of power rails.

14. The chip of claim 9, wherein the devices include transistors.

15. The chip of claim 9, wherein the first plurality of power rails is orientated perpendicular with respect to the second plurality of power rails.

16-23. (canceled)
